(19) United States
(12) Patent Application Publication
(10) Pub. No.: US 2024/0407194 A1
(43) Pub. Date: Dec. 5, 2024

(54) LIGHT-EMITTING DIODE (OLED) DISPLAY AND METHOD OF FABRICATION USING MULTIMODAL THREE-DIMENSIONAL (3D) PRINTING

(71) Applicant: REGENTS OF THE UNIVERSITY OF MINNESOTA, Minneapolis, MN (US)

(72) Inventors: Michael C. McAlpine, Minneapolis, MN (US); Ruitao Su, Allston, MN (US); Sung Hyun Park, Seongnam-si (KR)

(21) Appl. No.: 18/694,762

(22) PCT Filed: Sep. 22, 2022
(86) PCT No.: PCT/US2022/044322

§ 371 Date: Mar. 22, 2024

Related U.S. Application Data
(60) Provisional application No. 63/247,358, filed on Sep. 23, 2021.

(51) Int. Cl. H10K 59/12; H10K 59/131; H10K 59/80; H10K 71/13; H10K 71/60; H10K 85/10; H10K 102/00

(52) U.S. Cl. CPC H10K 59/1201; H10K 59/131; H10K 59/805; H10K 71/13; H10K 71/611; H10K 85/1135; H10K 2102/311; H10K 2102/351

(57) ABSTRACT

A multimodal method of three-dimensionally (3D) printing a light-emitting diode (LED) display includes extrusion printing a first conductive layer utilizing a first extrusion printing nozzle set, spray printing an active layer onto the first conductive layer utilizing a spray printing nozzle, and extrusion printing a second conductive layer utilizing a second extrusion printing nozzle set.

### CROSS-REFERENCE TO RELATED APPLICATIONS

This application claims the benefit of and priority to U.S. provisional application 63/247,358, titled “LIGHT-EMITTING DIODE (OLED) DISPLAY AND METHOD OF FABRICATION USING A MULTIMODAL THREE-DIMENSIONAL (3D) PRINTING TECHNIQUE”, filed Sep. 23, 2021 the contents of which are incorporated by reference herein.

### TECHNICAL FIELD

The invention relates generally to light-emitting diode (LED) displays, and in particular to three-dimensional (3D) printed flexible light-emitting diode (OLED) displays.

### BACKGROUND

Displays built with light-emitting diodes (LEDs)—including organic light-emitting diodes (OLEDs) and quantum dot LEDs—are emerging as competitive alternatives to liquid crystal displays (LCDs) because of their superior performance such as self-emission, high contrast ratio, wide viewing angle, low power consumption, and mechanical flexibility. Typically, in commercial OLED displays, the active layers (or emitting layers) are thermally evaporated to achieve uniform layers and high resolutions. Printing methods are being actively investigated due to the potential for scaling up to large panel displays and reduction on material wastage. Fully printed OLED displays in which all functional components are fabricated with printing methods could lead to futuristic concepts, such as higher dimensional form factors, displays interwoven with soft robotics for electroluminescent body parts and three-dimensionally (3D) structured pixel matrices for holographic displays. Yet, methodologies to fully print OLED displays require overcoming several challenges to transferring the materials and processes to printing platforms. While active layers could be printed in place of evaporated or spin-coated counterparts, electrodes, including anode and cathode, require sputtering or vapor deposition to achieve high electrical conductivity and optical transmittance with materials such as metals, metal-oxides, and graphene. In addition, plasma-enhanced deposition processes are typically required to produce oxide-based encapsulating layers with low moisture diffusion to improve device lifetime. Innovations in the material systems, device configuration, and printing processes and design modalities are required to comprehensively print next-generation displays in a manner which is completely untethered from conventional microfabrication manufacturing facilities.

### SUMMARY

According to some aspects, a multimodal method of three-dimensionally (3D) printing a light-emitting diode (LED) display includes extrusion printing a first conductive layer utilizing a first extrusion printing nozzle set, spray printing an active layer onto the first conductive layer utilizing a spray printing nozzle, and extrusion printing a second conductive layer utilizing a second extrusion printing nozzle set.

According to another aspect, an organic light-emitting diode (OLED) display comprised of a plurality of pixels, the OLED display includes a substrate, a bottom interconnect array fabricated on the substrate, the bottom interconnect array including a plurality of interconnect columns. The OLED display further includes a first conductive layer fabricated onto the bottom interconnect array and an active layer printed onto the first conductive layer. The OLED display further includes a second conductive layer extrusion printed onto the active layer, each contact in the second conductive layer comprising a droplet extrusion printed onto the active layer and mechanically reconfigured from a droplet geometry to a second configuration that increases a bottom contact area of the droplet, and a top interconnect array fabricated onto the second conductive layer, the top interconnect array including a plurality of interconnect rows, wherein the plurality of pixels are individually addressable utilizing the plurality of interconnect columns and the plurality of interconnect rows.

### BRIEF DESCRIPTION OF THE DRAWINGS

FIG. 1 is an exploded view of at least some layers of an organic light-emitting diode display according to some embodiments of the present invention.

FIG. 2A is a schematic view illustrating 3D fabrication of at least one of the layers using an extrusion process according to some embodiments of the present invention, and FIG. 2B is a schematic view illustrating 3D fabrication of at least one of the layers using a spray printing process according to some embodiments of the present invention.

FIG. 3A includes optical images taken of layer deposited using a spray-printing technique (top) and extrusion printing technique (bottom) according to some embodiments; FIG. 3B is a graph illustrating the surface profiles of active regions deposited utilizing spray-printed techniques and extrusion printing techniques according to some embodiments; FIG. 3C is a graph illustrating spray printing thickness as a function of spray time; FIG. 3D includes images illustrating luminescence as a function of active layer thickness and applied voltage; FIG. 3E is a I-V curve for various thickness active layers; FIG. 3F is a graph illustrating irradiance as a function of time for spray printed layers and extruded layers.

FIG. 4 is a schematic view of a nozzle utilized to reconfigure the morphology of a deposited droplet according to some embodiments.

FIG. 5A is a side view illustrating the process utilized to compress and deform the deposited droplet to reconfigure the morphology of the droplet according to some embodiments; FIG. 5B is a graph with images illustrating the compression depth of the nozzle utilized to reconfigure the droplet according to some embodiments; FIG. 5C is a chart illustrating compression force applied to the droplet over time and corresponding major ruptures along the surface of the droplet according to some embodiments; FIG. 5D is a side view illustrating ruptures formed along the exterior surface of the droplet according to some embodiments; FIG. 5E are scanning electron microscope (SEM) illustrating ruptures, folds, and wrinkles created on the reconfigured droplet according to some embodiments; FIG. 5F is a graph illustrating force-t curves of the four stages during reconfiguration and the repeatability of the process for a wide range of compression rates according to some embodiments; FIG. 5G is a plot of variations in morphological metrics including contact area and droplet height before and after reconfiguration for various compression rates according to some embodiments; and FIG. 5F is a plot of the relationship between the ratio of morphological metrics after and before reconfiguration for varying compression depths according to some embodiments.

FIG. 6 is a set of images demonstrating the fabrications steps utilized to fabricate the hybrid 3D printed OLED display according to some embodiments.

FIG. 7A is a schematic cross-sectional view of the various layers associated with the OLED display according to some embodiments; FIG. 7B is an optical cross-sectional view of the various layers associated with the OLED display according to some embodiments; FIG. 7C is a front view of the OLED display; FIG. 7D is a back view of the OLED display; and FIG. 7E is a circuit diagram of the data lines and scan lines used to address individual pixels/LEDs of the OLED display according to some embodiments.

FIG. 8 is a perspective view illustrating a flexible OLED display and various axes along which the flexible OLED can bend according to some embodiments.

### DETAILED DESCRIPTION

The present disclosure provides a system and method of fabricating light-emitting diode (LED) displays using 3D printing techniques. Discussions of systems and methods of fabricating organic light-emitting diodes (OLEDs) are utilized for illustrative purposes, but the systems and methods described herein could also be utilized in the fabrication of other LED displays, including for example quantum dot LEDs utilizing inorganic materials In particular, the present disclosure is directed toward a hybrid 3D printing and reconfiguration technique that enables 3D printing of an LED display on a single printing platform-although other embodiments may utilize separate printing platforms. In some embodiments, the hybrid 3D printing technique utilizes a combination of extrusion and spray deposition to fabricate the LED display. In some embodiments, electrodes, interconnects, insulation, and encapsulation are extrusion printed, while active layers are spray printed to provide uniform layer thickness. In some embodiments, liquid metal droplets utilized as contacts are mechanically reconfigured (i.e., via a pressing operation) to increase the contact area of the polymer-metal junctions and to provide a uniform contact array.

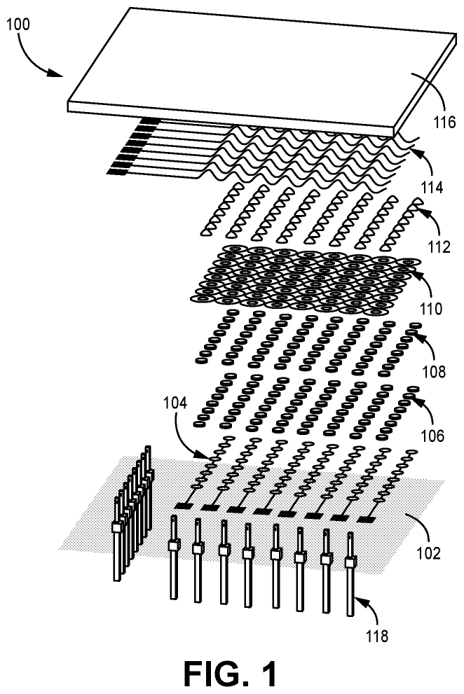

FIG. 1 is an exploded view of at least some layers of an organic light-emitting diode display 100 according to some embodiments of the present invention. According to at least one embodiment, the layers of the OLED display 100 include a substrate 102, bottom interconnect layer 104, a first conductive layer 106, an active layer 108, an insulation layer 110, a second conductive layer 112, a top interconnect array 114, and an encapsulation layer 116. In addition, a plurality of connection pins 118 may be included to connect the OLED display 100 to an external driving circuit (not shown).

In some embodiments, the substrate 102 is a flexible polyethylene terephthalate (PET) film. As discussed in more detail below, utilizing a PET film allows the OLED display 100 to be flexible in multiple directions. In other embodiments, the substrate 102 may be fabricated utilizing other materials that may or may not be flexible, depending on the required application. For example, in some embodiments the substrate 102 may be a semiconductor substrate. In other embodiments, substrate 102 may be a biological substrate (e.g., skin). In other embodiments, substrate 102 may be comprised of glass. In other embodiments, substrate 102 may be a thin film, such as a polyamide or polyimide material. In some embodiments, the substrate 102 may be a contact lens. Likewise, the geometry of the substrate 102 may be planar or non-planar.

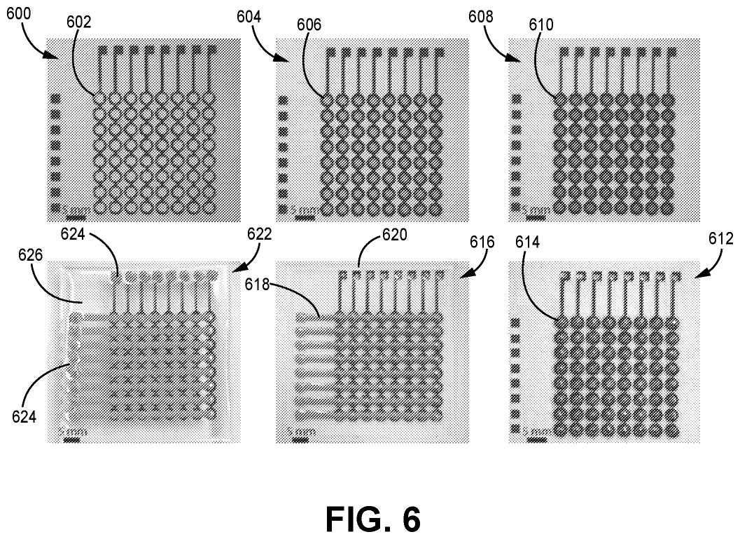

In some embodiments, the bottom interconnect array 104 is fabricated utilizing silver nanoparticles (AgNPs). The bottom interconnect array 104 defines the layout of the OLED matrices, which are connected to external driving circuits via connection pins 118. In some embodiments, the bottom interconnect array 104 defines a plurality of columns, each column connected to the plurality of pixels (e.g., active areas) included as part of the column. Adjacent columns are isolated from one another, meaning that each column is individually addressable. As described in more detail with respect to FIG. 6, in some embodiments the bottom interconnect layer 104 is extrusion printed onto the substrate using 3D printing. As described in more detail below, a benefit of utilizing extrusion printing techniques is that the bottom interconnect layer 104 may be deposited on non-planar surfaces (e.g., non-planar substrates 102). In other embodiments, however, the bottom interconnect layer 104 may be fabricated on the substrate 102 utilizing typical microfabrication techniques or other printing technologies.

In some embodiments, a first conductive layer 106 is fabricated on top of the bottom interconnect layer 104. In some embodiments, the first conductive layer 106 is separate from the bottom interconnect layer 104. In other embodiments, the first conductive layer 106 and the bottom interconnect layer 104 may be integral or deposited at the same step. In some embodiments, the first conductive layer 106 is extrusion printed onto the bottom interconnect array 104. In other embodiments, the first conductive layer 106 is fabricated utilizing traditional microfabrication techniques or other printing technologies

In some embodiments, the first conductive layer 106 is comprised of a conductive polymer. For example, in one embodiment the first conductive layer 106 comprises poly (3,4-ethylenedioxythiophene) polystyrene sulfonate (PEDOT:PSS) In some embodiments, the PEDOT:PSS material provides high conductive and optical transmittance that enhances the current injections provided to the active layer 108 (i.e., the electroluminescent layer) and enables light extraction from the device. In other embodiments, the first conductive layer 106 may be comprised of other materials, particularly those well-suited for use as a cathode/anode contact material in OLED matrices, such as mono-(Aluminum (Al), Samarium (Sm), Thulium (Tm), Terbium (Tb)) and/or bimetallic (Calcium:Aluminum (Ca:Al), Europium:Ytterbium (Eu:Yb), Thulium:Ytterbium (Tm:Yb)) materials, tris(8-hydroxyquinolinolato)aluminum-(III) (Alq3), N,N0-bis(3-methylphenyl)-N,N 0-diphenylbenzidine (i.e., TPD), Alq3, Al, Mg-Ag, LiF/Al, and/or MoO3.

In some embodiments, the active layer 108 (i.e., the electroluminescent layer) is comprised of a plurality of active regions (i.e., islands), each active region representing a pixel in the OLED display. In some embodiments, each island making up the electroluminescent polymer array 108 is fabricated utilizing poly(2-methoxy-5-(3′,7′-dimethyloctyloxy)-1,4-phenylenevinylene) (MDMO-PPV). In other embodiments, other electroluminescent materials may be utilized to fabricate array 108. For example, in some embodiments the array 108 may be fabricated using one or more of silicon nanocrystals, quantum dots comprised of one or more CdSe—ZnS, CdS, ZnSe, CdZnSe, ZnSeS, InP, GaN, CdeSe), perovskites (including but not limited to (CH₃CH₂CH₂NH₃)₂CsPb₂I₇, CsPbBrₓCl_{3×x}, Cs_{0.2}FA_{0.8}Pb(IₓBr₁₋ₓ)₃), and polymers (including but not limited to poly(p-phenylenevinylene) (PPV), poly[2-methoxy-5-(2-ethylhexyloxy)-1,4-phenylenevinylene (MEH:PPV)), cyano-PPV, poly(N-vinylcarbazole), carbazole-oxadiazole complexes), as well as combination of one or more of these materials. Light is generated by individual islands making up the active or electroluminescent layer 108 via the recombination of electrons and holes within the layer.

As described in more detail below, in some embodiments the active layer is fabricated utilizing a spray printing technique. In some embodiments, spray printing techniques allow the thickness of the deposited layer to be more easily controlled as well as providing a more uniform thickness that improves performance as compared to active layers deposited utilizing extrusion techniques.

In some embodiments, the insulation layer 110 is fabricated utilizing silicone-based insulation layer that acts to separate the bottom interconnect array 104 from the second conductive layer 112 and the top interconnect array 114. In some embodiments, the insulation layer 110 is printed to cover all conductive materials underneath such that only the active layers/regions 108 are exposed to the second conductive layer 112 fabricated on top of the insulation layer 110. In some embodiments, the second conductive layer 112 that includes a plurality of individual regions extrusion printed onto the respective active layers/regions 108. In some embodiments, the extrusion printed regions are deposited as individual droplets which are then reconfigured via a pressing action to improve the contact surface area between each droplet and the corresponding active layers/regions 108. In some embodiments, the second conductive layer 112 is fabricated from eutectic gallium indium (EGaIn). In other embodiments, the second conductive layer 112 may be fabricated from other materials, such as one or more of Cu-EgaIn, galinstan, aluminum, silicon, gold, silver, palladium, conductive polymers (such as poly (3,4-ethylenedioxythiophene) polystyrene sulfonate (PEDOT:PSS), poly(4-glycidyloxy-2,2,6,6-tetramethylpiperidine-1-oxyl) (PTEO), polyaniline, polypyrrole, and others) and metallic layers that are modified with interlayers (such as lithium fluoride, perylene-diimide, lanthanides, polyethylenimine and others.). In still other embodiments, the second conductive layer 112 may be fabricated from eutectic gallium indium/silicone composites. In some embodiments, the second conductive layer 112 acts as the anode/cathode to the active layer 108. For example, if the first conductive layer 106 acts as an anode then the second conductive layer 112 acts as a cathode and vice versa. The top interconnect array 114 is fabricated on top of the second conductive layer 112, and is organized into a plurality of rows, each row contacting a plurality of the droplets associated with the second conductive layer 112. Adjacent rows of the top interconnect array 114 are isolated from one another. The combination of the plurality of columns making up the bottom interconnect array 104 and the plurality of rows making up the top interconnect array 114 allows for each individual pixel (each individual active region of the electroluminescent polymer array) to be individually addressable via selection of the desired row and desired column. In some embodiments, the top interconnect array 114 is fabricated utilizing a silver (Ag) paste and may be extrusion printed to conform to the surface geometry of the second conductive layer 112, deposited as droplets and subsequently reconfigured. In some embodiments, the 3D printhead utilized to extrusion print the top interconnect array 114 is required to move in both a lateral direction and vertical direction to accommodate the surface geometry of the second conductive layer 112 and/or the surface topology of the substrate. One of the benefits of utilizing 3D extrusion printing and/or 3D spray printing techniques is that the printheads and/or spray heads may be moved in both the lateral direction and vertical direction and can therefore accommodate various geometries. For example, as discussed previously, the substrate 102 may be non-planar and yet accommodated by the 3D printing techniques. In some embodiments, the encapsulation layer 116 is fabricated utilizing polydimethylsiloxane (PDMS). In some embodiments, the device is cast into an extrusion printed silicone mold that forms a flexible and transparent top layer after cross-linking.

As described in more detail below, the stacking of each of the layers shown in FIG. 1 allows the layers to be printed utilizing 3D printing techniques. In addition, the multimodal 3D printing techniques described herein can be performed at room temperature without requiring convention microfabrication facilities. While the layers shown in FIG. 1 may be fabricated entirely utilizing the multi-modal (e.g., extrusion printing, spray printing, etc.) 3D printing techniques, in other embodiments one or more of the layers shown in FIG. 1 may be fabricated utilizing traditional techniques. For example, in some embodiments the bottom interconnect layer 104 may be fabricated utilizing traditional fabrication techniques, with at least some of the layers fabricated utilizing the multi-modal 3D printing techniques.

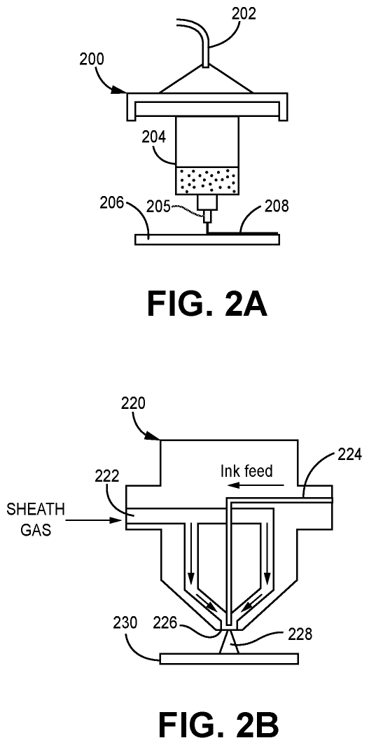

Referring now to FIGS. 2A-2B, schematic diagrams are provided illustrating extrusion printing techniques and spray-printing techniques utilized as part of the multimodal or hybrid 3D printing process of OLED displays. For example, FIG. 2A is a schematic view illustrating 3D fabrication of at least one of the layers using an extrusion process according to some embodiments of the present invention. FIG. 2B is a schematic view illustrating 3D fabrication of at least one of the layers using a spray printing process according to some embodiments of the present invention.

As described in more detail below, one or more of the layers may be fabricated utilizing extrusion printing techniques and one or more of the layers may be fabricated utilizing spray-painting techniques. For example, in some embodiments, extrusion 3D printing techniques are utilized to fabricate the bottom interconnect array 104, the first conductive layer 106, the insulation layer 110, the second conductive layer 112, and the top interconnect array 114. In some embodiments, spray printing techniques are utilized to fabricate the active layer 108 (e.g., the electroluminescent layer). In particular, the performance of OLEDs is affected by the uniformity and thickness of the active layer 108. In some embodiments, utilizing a spray printing method to deposit the active layer 108 provides better uniformity and controllable thickness as compared with extrusion printed techniques.

In the embodiment shown in FIG. 2A, the printing nozzle 200 mounted on the extrusion 3D printer (not shown) includes a pressurized input 202, a printing reservoir 204, and a nozzle head 205. Material stored within the printing reservoir 204 is forced through the nozzle head 205 (i.e., extruded) via the application of pressure at the pressurized input 202. Depending on the material being extruded, various pressures may be utilized. The extruded material 208 is deposited onto the underlying layer (e.g., substrate 206). Various types of material utilized by the various layers may be extruded in this manner. In some embodiments, the same printing nozzle 200 is utilized for all extrusion printed layers. In other embodiments, different printing nozzles may be utilized depending on the layer to be deposited. In addition, in some embodiments, the printing nozzle may be selected based on whether mechanical reconfiguration of the extruded material is required, wherein the printing nozzle may be utilized to press on the material to perform the necessary mechanical reconfiguration.

In the embodiment shown in FIG. 2B, a schematic view of a spray printing device 220 is shown, which includes gas line 222, an ink feed line 224, and orifice 226. The material to be deposited is provided via ink feed line 224 to the orifice 226. The ink (material to be spray printed) is atomized at the orifice 226 where a high relative speed is created between the near-static ink and the pressurized sheath gas provided via gas line 222. The atomized droplets 228 are rapidly evaporated after impacting the substrate 230, rendering a suppressed mass transport in the lateral direction. The suppression of the mass transport in the lateral direction allows micro-droplets to be uniformly distributed across the target area at a desired thickness (reduced thickness if desirable). As described in more detail below, the ability to reduce the thickness of some of the layers (in particular, the active layers) and to increase uniformity of the deposited layer is highly desirable. In particular, increased uniformity and reduced thickness improves the performance of the individual pixels.

In some embodiments, the spray printing fabrication method is utilized to deposit the active layer 108, which may consist of a plurality of circular areas. In some embodiments, the spray printing fabrication method is utilized to enable the formation of dot patterns and/or continuous lines with feature sizes as small as 1 mm on both planar and 3D surfaces.

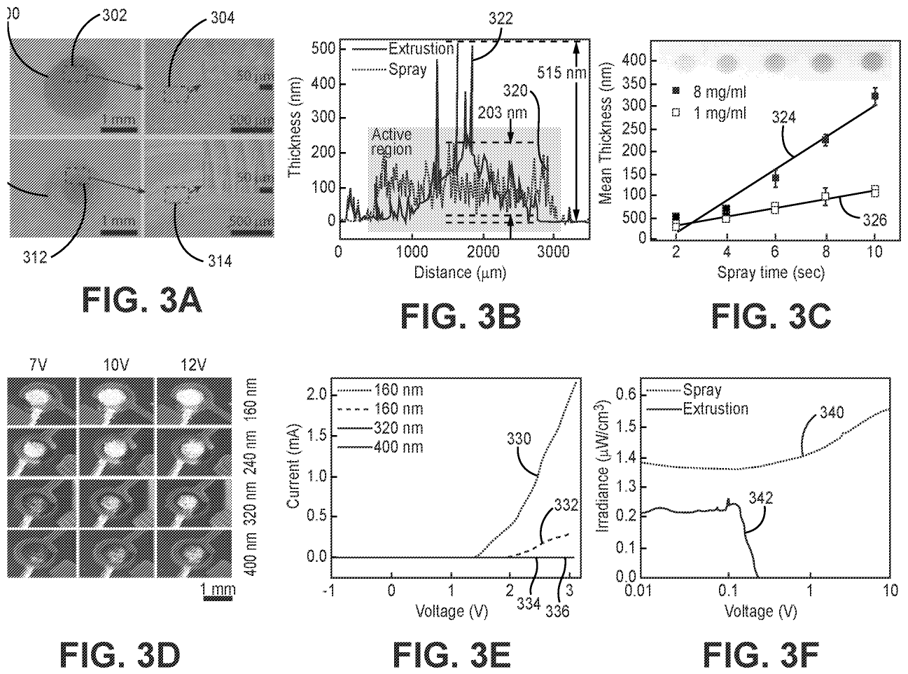

FIGS. 3A-3F provide a comparison of active regions deposited utilizing spray printing techniques as compared with active regions deposited utilizing extrusion techniques. For example, FIG. 3A illustrates optical images taken of circular layers deposited via spray-printing process (300) and extrusion process (310). As illustrated in FIG. 3A, the spray printing process provides a more uniform and clearly defined circular region 300 as compared with the circular region 310 printed using extrusion techniques. Regions 302 (top, spray-printed) and 312 (bottom, extruded) are magnified in the images shown to the right, and further magnified as illustrated by regions 304 (top) and 314 (bottom). As shown in the magnified views, the spray-printed circular region is more uniformly deposited than the circular region deposited utilizing extrusion techniques. FIG. 3B illustrates the measured surface profiles of the spray-printed (line 320) and extruded (line 322) circular regions. As shown, the spray-printed region has less variation and a more uniform surface profile. In particular, the spray-printed active region (line 320) has a surface peak-to-peak variation of 203 nm with a mean thickness of 94 nm and a standard deviation of 37 nm. In some embodiments, this allows the spray printed regions (e.g., for example, the electroluminescent polymer array) to have a controllable mean thickness from tens of nanometers to several micrometers and a surface peak-to-peak variation of approximately 200 nanometers. By comparison, extrusion printed layers (line 322) according to some embodiments display greater peak-to-peak variation (515 nm) and greater mean thickness. The improved layer quality achieved via the spray printing technique facilitates more intimate contacts between adjacent layers and promotes the transport and recombination of electrons and holes across different layers, resulting in improved brightness and uniform light emission. In some embodiments, increased emission areas and irradiance of the spray printed OLEDs was observed as compared with OLEDs relying on extrusion printed active areas.

In some embodiments, the thickness of the spray printed active layers (e.g., electroluminescent polymer array 108) depends on the cumulative spray time and ink concentration. In some embodiments, layer thicknesses of the spray-printed active regions 108 (e.g., MDMO-PPV) increased linearly as a function of the spray time at a given ink concentration (as shown in FIG. 3C). In particular, a concentration of 8 mg/ml (shown by line 324) provides a steeper curve than a concentration of 1 mg/ml (shown by line 326), but both concentrations result in relatively linear increases in thickness over time. Changes in ink concentrations induced variations in viscosity and hence in the spray behavior. Various ink concentrations and spray times may be utilized based on the desired thickness of the layer to be deposited (e.g., electroluminescent polymer array layer).

As a result of the decreased thickness in the deposited active layers (e.g., electroluminescent polymer array 108) achieved utilizing spray-printing techniques, increased luminescence was observed as shown in FIG. 3D. The top row is defined by a thickness of approximately 160 nm, then 240 nm, 320 nm, and 400 nm. Each column represents an applied voltage, including 7 Volts (V), 10 V, and 12 V. As shown in FIG. 3D, luminescence increases with increased voltage and with decreased thickness of the active layer. As shown in FIG. 3E, the voltage required to induce current (and therefore luminescence) is illustrated for various thickness active regions (160 nm—line 330, 240 nm—line 332, 320 nm—line 334, and 400 nm—line 336). As illustrated in FIG. 3E, current is induced at lower voltages as the thickness is decreased. FIG. 3F illustrates the relationship between irradiance and operation time for displays fabricated utilizing spray printed active regions (line 340) as compared with displays fabricated utilizing extruded active regions (line 342). As illustrated, spray printed active regions provide improved operation time.

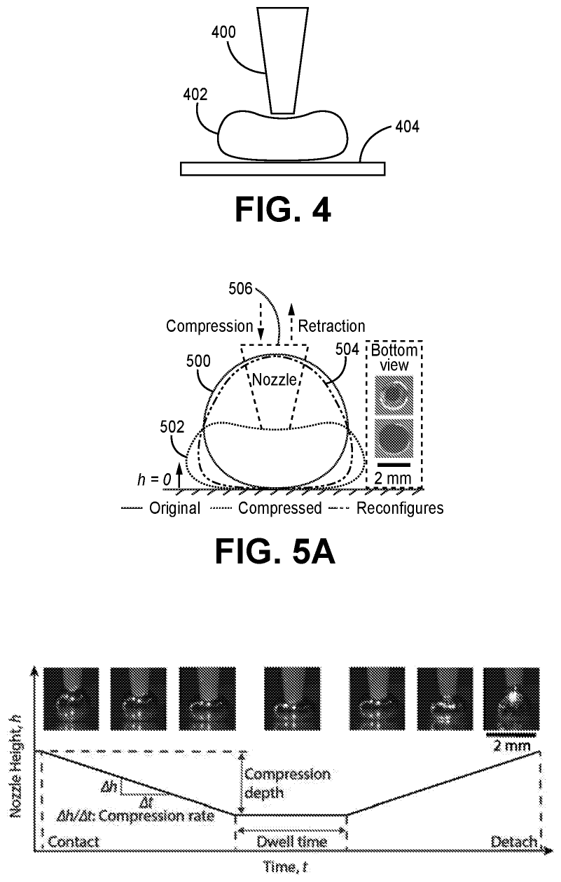

FIG. 4 is a schematic view illustrating reconfiguration of one of the layers using the printing nozzle to deform the layer according to some embodiments of the present invention. As described with respect to FIG. 1, one or more layers may be reconfigured via a pressing action that results in a morphological variation of deposited layer (or in this case, droplet). The morphological variation improves the contact surface area between each droplet and the corresponding underlying layer (e.g., improves the contact surface area between the second conductive layer 112 and underlying active layer 108). In some embodiments, the printing nozzle 400 is utilized to deposit a liquid metal droplet (e.g., eutectic gallium indium (EGaIn) 402 via an extrusion process. In some embodiments, the same printing nozzle 400 utilized to deposit the droplet 402 is utilized to press against the droplet 402, which deforms the droplet 402 such that contact area between the droplet 402 and the underlying layer 404 is increased. In other embodiments, a first printing nozzle is utilized to deposit the droplet 402 and a second nozzle is utilized to deform the droplet 402.

In some embodiments, the printing nozzle 400 utilized to deform the droplet 402 is a polypropylene nozzle. To deform the droplet 402, the printing nozzle 400 may be programmed to move in a vertical direction. Attributes of the programmed movement may include compression rate, dwell time, and compression depth.

In some embodiments, the reconfiguration (i.e., deformation) of the droplet 402 depends in part on the material selected for the droplet 402. For example, in some embodiments the droplet is extruded utilizing a eutectic gallium indium (EGaIn) material. In some embodiments, following extrusion of the EGaIn material, an oxide composed generally of Ga₂O₃ is formed on the surface of the droplet 402. In some embodiments, the morphology of the droplet varies during both the compression and removal of the nozzle.

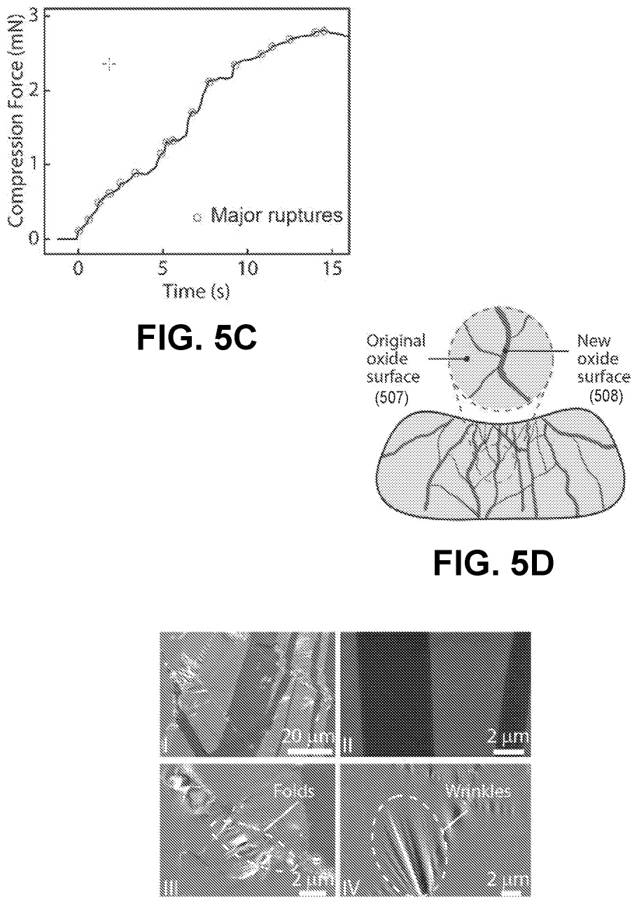

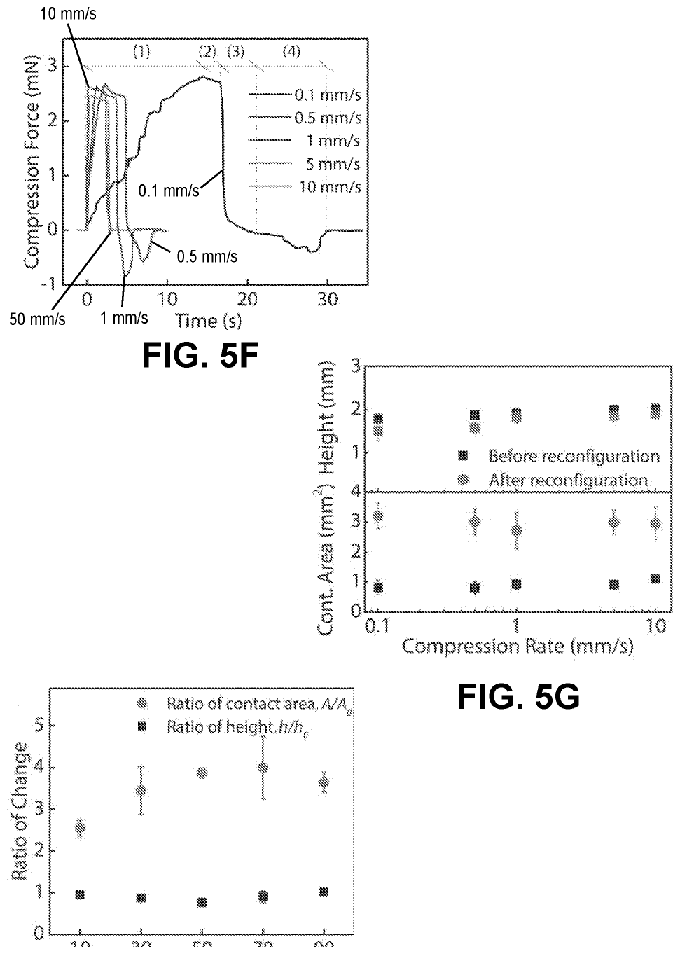

Referring to FIGS. 5A-5E, the reconfiguration of droplets is described in additional detail. During the interaction with the designed nozzle motion, the force-time behavior of the droplet can be divided into four stages: (1) compression stage where the compression force increased as the droplets were compressed and the oxide surface ruptured, (2) dwell stage where the nozzle halted and the compression force decreased because of the gradual relaxation of the compressed oxide skin, (3) rapid relaxation stage as the nozzle started retracting, and (4) pulling stage as the nozzle further retracted and adhesion pulled the droplets until detachment occurred. FIG. 5A illustrates some of these stages, illustrating the droplet 500 prior to the compression stage when the droplet is largely circular (no deformation of the droplet, illustrating the droplet 502 when fully compressed and the nozzle is halted at the maximum compression depth (fully deformed), and following removal of the nozzle and relaxation of the reconfigured droplet 504. FIG. 5B illustrates the deformation of the droplet at various stages, along with a graph illustrating the nozzle height h plotted against time t. In the first stage, the droplet 500 is relatively circular prior to deformation by the nozzle 506. During the second stage, the nozzle is fully depressed to a desired compression depth and the droplet 502 is fully deformed. As shown in FIG. 5B, in some embodiments the nozzle remains depressed for a period of time, referred to as the dwell time. In some embodiments, dwell time may affect the contact area of the reconfigured droplet and/or height of the reconfigured droplet. In other embodiments, in particular those utilizing EGaIn droplets, the dwell time seemed to have no affect on the contact area of the reconfigured droplet and/or height of the reconfigured droplet. This is despite an observed gradual relaxation of the oxide surface during the dwell time. As the nozzle 506 is removed, the droplet 504 takes on the final morphology shown in the third stage. In some embodiments, the height of the droplet 500 in the first stage is approximately equal to the height of the droplet 504 in the third stage. However, the contact surface area between the droplet and underlying surface in the third stage is greater than the contact surface area of the droplet in the first stage. Because the metallic core has a low viscosity, the mechanical behavior of the EGaIn droplet is dominated by that of the oxide surface. That is, due to the viscoelasticity of the Ga₂O₃ oxide, the oxide surface would yield or flow as the local surface stress increased above the yield strength and rupture as the surface stress further increased. At the rupture sites, part of the metallic core was exposed to the air and rapidly oxidized again. The new and original oxide skin connected and reconstructed a complete oxide shell, evidenced by the networks of original and new surface patterns on the droplets (as shown in FIG. 5E, for example). In this way, the oxide shell wrapping the droplets (e.g., EGaIn droplets) underwent a rupture-and-reoxidation process during reconfiguration and the cathode structure was “forged” into a new and stable morphology Reconfiguration or deformation of the droplets is highly repeatable in terms of mechanical behavior, junction contact areas, and geometric profiles of the resulting cathode structure.

FIGS. 5C-5H illustrates the various aspects of the ruptures resulting from the compression forces. For example, FIG. 5C is a force curve that illustrates an increasing trend for the force applied to the droplet as the nozzle is moved downward, with major rupture sites illustrated by corresponding circles. FIG. 5D is a cross-sectional view of the droplet that illustrates the formation of new oxide surfaces during surface ruptures. The original oxide surface 507 is relatively smooth, wherein the new oxide surface 508 is formed at the junction of the ruptures. The new and original oxide shell generated following reconstruction of the droplet is shown in the scanning electron microscope (SEM) view of the droplet shown in boxes I, II, III, and IV of FIG. 5E. In particular, box I (zoomed out) illustrates the coexistence of several features along the surface of the droplet. Box II is a zoomed in view illustrating the boundary between the original and new oxide surfaces created by the surface ruptures. Box III is a zoomed in view of folds along the oxide surface formed during retraction of the nozzle. Box IV is a zoomed in view of the wrinkles formed on the oxide surface during surface relaxation.

FIG. 5F is a force-time curve that demonstrates the four stages during reconfiguration and the high repeatability of his process for a wide range of compression rate. FIG. 5G is a plot of variations of the morphological metrics, including junction contacting area and droplet height of the droplets, before and after reconfiguration for compression rates spanning three orders of magnitude. FIG. 5H is a plot of the relationship between the ratio of morphological metrics after and before reconfiguration and varying compression depths.

FIG. 6 is a diagram illustrating fabrication of the flexible OLED display. At step 600, the bottom interconnects 602 are extrusion printed. In some embodiments, the bottom interconnects 602 are fabricated utilizing silver nanoparticles (AgNPs). At step 604, the first conductive layer (e.g., anode/cathode) 606 are extrusion printed In some embodiments, the first conductive layer 606 are fabricated utilizing poly (3,4-ethylenedioxythiophene) polystyrene sulfonate (PEDOT:PSS). In other embodiments, the first conductive layer 606 may be comprised of other materials, particularly those well-suited for use as a cathode/anode contact material in OLED matrices, such as mono-(Aluminum (Al), Samarium (Sm), Thulium (Tm), Terbium (Tb)) and/or bimetallic (Calcium:Aluminum (Ca:Al), Europium:Ytterbium (Eu:Yb), Thulium:Ytterbium (Tm:Yb)) materials, tris(8-hydroxyquinolinolato) aluminum-(III) (Alq3), N,N0-bis(3-methylphenyl)-N,N 0-diphenylbenzidine (i.e., TPD), Alq3, Al, Mg-Ag, LiF/Al, and/or MoO3.

At step 608, the active layer (i.e., electroluminescent polymer) 610 is spray printed on top of the first conductive layer 606. In some embodiments, the active layer or electroluminescent polymer 610 is poly(2-methoxy-5-(3′,7′-dimethyloctyloxy)-1,4-phenylenevinylene) (MDMO-PPV). At step 612, an insulating layer (not shown) and second conductive layer 614 is extrusion printed. In some embodiments, the insulating layer is silicone and the second conductive layer 614 is eutectic gallium indium (EGaIn). As described above, in some embodiments the second conductive layer 614 is deposited as a droplet that is subsequently reconfigured to improve the contact surface area between the second conductive layer 614 and the active layer 610. At step 616, a top interconnect layer 618 is extruded as a row across each of the second conductive layer 614. In some embodiments, the top interconnect layer 618 is a silver paste (Ag). In this way, each pixel is individual addressable via selective activation of a particular bottom interconnect column 602 and a particular top interconnect row 618. In some embodiments, the reconfiguration nozzle utilizes to reconfigure the droplets is pre-loaded with the conductive paste (e.g., Ag) formulated with an epoxy matrix and micro-sized silver fillers. In some embodiments, the nozzle path for the extrusion of the top interconnect layer 618 takes into account the morphology of the reconfigured second conductive layer 614 (e.g., reconfigured droplets) so that the top interconnect layer 618 is conformally interfaced with the second conductive layer 614. In addition, a silicone retainer 620 is extruded around the periphery of the rows and columns. At step 622, connection pins were plugged into the silver pads and an encapsulation layer 626 is cast using the silicone retainer 620 as a barrier. In some embodiments, the encapsulation layer 626 is a polydimethylsiloxane (PDMS) utilized to encapsulate the OLED display.

In some embodiments, the top interconnect layer 618 and the bottom interconnect layer 602 are separated by the insulating layer (e.g., silicone). The column structure of the bottom interconnect layer 602 and the row structure of the top interconnect layer 618 allows each pixel to be individually addressable. In addition, the fabrication method described herein allows for both metallization layers (e.g., top, bottom interconnects) and thin film layers (e.g., active layer or electroluminescent polymer 610) can be printed utilizing the multimodal 3D printing technique. A benefit of the multimodal 3D printing technique is that complex circuit layout and photomasking techniques normally utilized in microelectronics fabrication are not required.

In some embodiments, the bottom interconnect layer 602 and the first conductive layer (e.g., anode/cathode layer) 606 are extruded utilizing a first extrusion nozzle. In some embodiments, the pressure (pounds per square inch (psi)) utilized to extrude the bottom interconnect layer 602 is less than the psi utilized to extrude the bottom anode layer 606. In some embodiments, the first extrusion nozzle is stainless steel and has an inner diameter of 100 μm. In some embodiments, the active layer or electroluminescent polymer 610 is spray printed utilizing a spray nozzle. In some embodiments, the second conductive layer (e.g., anode/cathode layer) 614 and top interconnect layer 618 are extruded utilizing a second extrusion nozzle. In some embodiments, the psi utilized to extrude the second conductive layer 614 is less than the psi utilized to extrude the top interconnect layer 618. In some embodiments, the second extrusion nozzle is utilized to reconfigure the morphology of the second conductive layer 614 via a pressing operation. In some embodiments, the second extrusion nozzle is a tapered polypropylene nozzle.

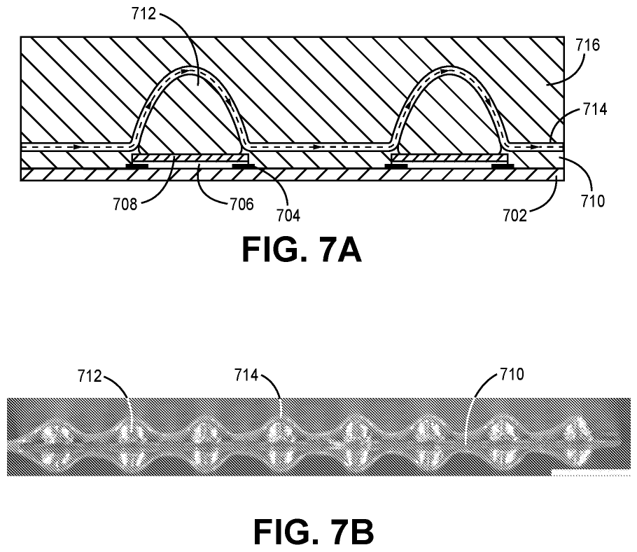

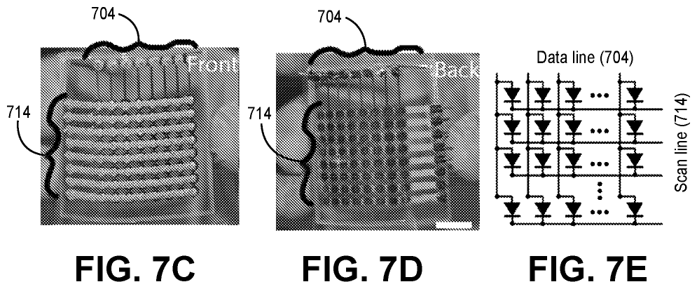

FIG. 7A is a schematic cross-sectional view of the various layers associated with the OLED display according to some embodiments; FIG. 7B is an optical cross-sectional view of the various layers associated with the OLED display according to some embodiments; FIG. 7C is a front view of the OLED display; FIG. 7D is a back view of the OLED display; and FIG. 7E is a circuit diagram of the data lines and scan lines used to address individual pixels/LEDs of the OLED display according to some embodiments. In the cross-sectional view shown in FIG. 7A, the various layers displayed include a substrate 702, bottom interconnect layer 704, a first conductive layer 706, an electroluminescent polymer layer 708, an insulation layer 710, a second conductive layer 712, a top interconnect layer 714, and an encapsulation layer 716.

FIG. 7B is an optical side view of the OLED display prior to encapsulation. The embodiment shown in FIG. 7B utilizes the same layers as that shown in FIG. 7A. In particular, in the embodiment shown in FIG. 7B illustrates an embodiments in which the substrate 702 is a flexible polyethylene terephthalate (PET) film, the bottom interconnect layer 704 comprises silver nanoparticles (AgNPs), the first conductive layer 706 comprises poly (3,4-ethylenedioxythiophene) polystyrene sulfonate (PEDOT:PSS), which together with the bottom interconnect layer 704 forms a composite anode structure, the electroluminescent polymer layer or active layer 708 comprises poly(2-methoxy-5-(3′,7′-dimethyloctyloxy)-1,4-phenylenevinylene) (MDMO-PPV), the insulation layer 710 comprises a silicone-based insulator, the second conductive layer 712 comprises eutectic gallium indium (EGaIn), the top interconnect layer 714 comprises silver (Ag) paste, and the encapsulation layer 716 comprises polydimethylsiloxane (PDMS). In the embodiment shown in FIG. 7B, the top interconnect layer 714 is conformally printed over the reconfigured cathode layer 712. In the view shown in FIG. 7A and 7B, the pixels illustrated exist along the same row connected together via the top interconnect layer 714. The bottom interconnect layer 704 associated with the first and second OLED pixels are not connected to one another, but rather would be connected as part of two different columns of interconnect layers. This configuration is illustrated in the circuit schematic shown in FIG. 7E, which includes a plurality of data lines corresponding with bottom interconnect array 704 and a plurality of scan lines corresponding with top interconnect array 714, wherein the intersection of each bottom interconnect column and each top interconnect row corresponds with an addressable OLED pixel.

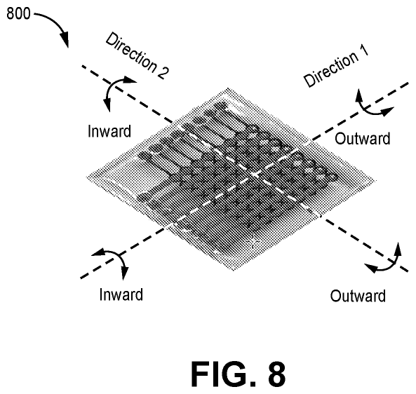

FIG. 8 is a perspective view illustrating a flexible OLED display 800 and various axes 802, 804 along which the flexible OLED can bend according to some embodiments. The ability to fabricate a flexible OLED display 800 is a function of the ability to 3D print the various layers of the OLED display on a flexible substrate. In addition, because 3D printing techniques are utilized, the OLED display 800 may be printed or fabricated on non-planar surfaces. For example, FIGS. 9B-9C illustrate several examples of non-planar applications for printing flexible OLED displays, including a spherical surface (FIG. 9B) and a freeform surface of a hand model (FIG. 9C).

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention is not limited to the particular embodiment(s) disclosed, but that the invention will include all embodiments falling within the scope of the appended claims.

1. A multimodal method of three-dimensionally (3D) printing a light-emitting diode (LED) display, the method comprising:
extrusion printing a first conductive layer utilizing a first extrusion printing nozzle set;
spray printing an active layer onto the first conductive layer utilizing a spray printing nozzle; and
extrusion printing a second conductive layer utilizing a second extrusion printing nozzle set.

2. The multi-modal method of claim 1, further including:
extrusion printing a mold that encloses the LED display with a third extrusion printing nozzle set, wherein the mold is subsequently cast with an encapsulation material.

3. The multimodal method of claim 1, wherein the first extrusion printing nozzle set has a different configuration than the second extrusion printing nozzle set.

4. The multimodal method of claim 1, wherein extrusion printing the second conductive layer includes extrusion printing one or more droplets using the second extrusion printing nozzle set and subsequently reconfiguring the one or more droplets via a pressing operation that modifies a morphology of each extruded droplet.

5. The multimodal method of claim 4, wherein the second extrusion printing nozzle set is utilized to implement the pressing operation to reconfigure the one or more droplets.

6. The multimodal method of claim 4, wherein the reconfiguration of the one or more droplets results in an increase in contact surface area between the cathode array and the electroluminescent polymer array.

7. The multimodal method of claim 4, wherein the reconfiguration of the one or more droplets results in a uniformly distributed array with repeatable geometries.

8. The multimodal method of claim 1, wherein the second conductive layer is comprised of one or more of eutectic gallium indium (EGaIn), alloys of EGaIn such as Cu-EGaIn, Galinstan, aluminum, silicon, gold, silver, palladium, poly (3,4-ethylenedioxythiophene) polystyrene sulfonate (PEDOT:PSS), poly(4-glycidyloxy-2,2,6,6-tetramethylpiperidine-1-oxyl) (PTEO), polyaniline, polypyrrole, and metallic layers modified with an interlayer comprised of one or more of lithium fluoride, perylene-diimide, lanthanides, and polyethylenimine.

9. The multimodal method of claim 1, wherein the active layer is comprised of one or more of poly(2-methoxy-5-(3′,7′-dimethyloctyloxy)-1,4-phenylenevinylene) (MDMO-PPV), silicon nanocrystals, quantum dots comprised of one or more of CdSe—ZnS, CdS, ZnSe, CdZnSe, ZnSeS, CdS, GaN and InP, perovskites comprised of one or more of (CH₃CH₂CH₂NH₃)₂CsPb₂I₇, CsPbBrₓCl₃₋ₓ, Cs_{0.2}FA_{0.8}Pb(IₓBr₁₋ₓ)₃, and polymers including one or more of poly(p-phenylenevinylene) (PPV), poly[2-methoxy-5-(2-ethylhexyloxy)-1,4-phenylenevinylene] (MEH:PPV)), cyano-PPV, poly(N-vinylcarbazole), and carbazole-oxadiazole complexes, and combinations thereof.

10. The multimodal method of claim 1, wherein the active layer has a thickness that is a function of cumulative spray time.

11. The multimodal method of claim 10, wherein the active layer has a controllable mean thickness in a range of 50-200 nm by varying the cumulative spray time and a surface peak-to-peak variation of approximately 200 nanometers.

12. The multimodal method of claim 1, wherein a first extrusion printing nozzle set, the spray printing nozzle, and/or the second extrusion printing nozzle set move both laterally and vertically.

13. An organic light-emitting diode (OLED) display comprised of a plurality of pixels, the OLED display comprising:
a substrate;
a bottom interconnect array fabricated on the substrate, the bottom interconnect array including a plurality of interconnect columns;
a first conductive layer fabricated onto the bottom interconnect array;
an active layer printed onto the first conductive layer;
a second conductive layer extrusion printed onto the active layer, each contact in the second conductive layer comprising a droplet extrusion printed onto the active layer and mechanically reconfigured from a droplet geometry to a second configuration that increases a bottom contact area of the droplet; and
a top interconnect array fabricated onto the second conductive layer, the top interconnect array including a plurality of interconnect rows, wherein the plurality of pixels are individually addressable utilizing the plurality of interconnect columns and the plurality of interconnect rows.

14. The OLED display of claim 13, wherein the substrate is planar.

15. The OLED display of claim 13, wherein the substrate is non-planar.

16. The OLED display of claim 13, wherein the substrate is flexible.

17. The OLED display of claim 13, wherein a thickness of the active layer has a controllable mean thickness in a range of 50-200 nm by varying a cumulative spray time and a surface peak-to-peak variation of approximately 200 nanometers.

18. The OLED display of claim 13, wherein the bottom interconnect array is extrusion printed onto the substrate

19. The OLED display of claim 13, wherein an oxide shell forms around an outer surface of each extruded droplet, wherein mechanical reconfiguration of each extruded droplet results in formation of a plurality of rupture-and-reoxidation processes along the extruded droplet.

20. The OLED display of claim 19, wherein the second conductive layer is comprised of eutectic gallium indium (EGaIn) and the oxide shell formed on the outer surface of each extruded droplet is comprised of Ga₂O₃.

21. The OLED display of claim 13, wherein each interconnect row of the top interconnect array is extrusion printed to conform to a surface profile of the second conductive layer, wherein the surface profile of the second conductive layer is non-planar due to the plurality of reconfigured extruded droplets.
